(19) United States
(12) Patent Application Publication
(10) Pub. No.: US 2010/0059889 A1
(43) Pub. Date: Mar. 11, 2010

(54) ADHESION OF DIFFUSION BARRIER ON COPPER-CONTAINING INTERCONNECT ELEMENT

(75) Inventors: Laurent Georges Gosset, Grenoble (FR); Joaquin Torres, Saint Martin Le Vinoux (FR); Sonarith Chhun, La Trinite (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/520,189

(22) PCT Filed: Dec. 7, 2007
(86) PCT No.: PCT/EP2007/063552

§ 371 Date: Nov. 6, 2009

(30) Foreign Application Priority Data
Dec. 20, 2006 (EP) 06292016.0

(51) Int. Cl. H01L 23/532; H01L 21/768; H01L 21/321

(52) U.S. Cl. 257/751; 438/778; 257/E21.575; 257/E23.154

(57) ABSTRACT

The present invention relates to a method for fabricating a semiconductor device. For improving the adhesion between a copper-containing interconnect element and a diffusion barrier on top of it, a first dielectric layer (108) of a first dielectric material is deposited on an exposed surface (102.1) of the interconnect element. Susequently, particles (110) are implanted into the first dielectric layer and the interconnect element (102) so as to let the interconnect material mix with the first dielectric material in a first interface region (102.2) between the interconnect element and the first dielectric layer.

### FIELD OF THE INVENTION

The present invention relates to a semiconductor device that comprises an interconnect element of a copper-containing interconnect material, and a first dielectric layer of a first dielectric material that covers the interconnect element. The invention further relates to a method for fabricating a semiconductor device that comprises the steps of providing a substrate with a surface that contains an interconnect element of a copper-containing interconnect material, and of depositing a first dielectric layer of a first dielectric material on the surface.

### BACKGROUND OF THE INVENTION

Self-aligned barrier caps on interconnect elements of a copper-containing interconnect material have been investigated for various reasons. P. Dumont-Girard et al., “Investigation of an advanced SiH₄ based self-aligned barrier process for Cu BEOL reliability performance improvement on industrial 110 nm technology”, Proceedings of the IEEE 2005 International Interconnect Technology Conference, Piscataway, N.J., USA, Jun. 6-8, 2005, pages 132-134, describe that self-aligned barriers are expected to reduce the final dielectric constant of an interconnect stack in the most advanced technology nodes for the fabrication of integrated circuits (ICs).

According to this document, a diffusion-barrier cap that is arranged between the interconnect element and the first dielectric layer can be fabricated by selective surface treatment of a Cu interconnect element, based on a selective reaction of a silane SiH₄ precursor with the Cu surface. This treatment leads to the formation of a Cu/Si/N mixed layer at the Cu surface. Subsequently, SiN is deposited, resulting in a self-aligned diffusion-barrier cap. A strong adhesion of the diffusion-barrier cap was observed.

### SUMMARY OF THE INVENTION

The following description first turns to the method aspect of the invention, which should allow an easier understanding. Subsequently, the device aspect of the invention will be described.

According to a first aspect of the invention, a method for fabricating a semiconductor device is provided. The method comprises:

providing a substrate with a surface that contains an interconnect element of a copper-containing interconnect material;

depositing a first dielectric layer of a first dielectric material on the surface;

implanting particles into the first dielectric layer and the interconnect element so as to let the interconnect material mix with the first dielectric material in a first interface region between the interconnect element and the first dielectric layer.

The method of the invention has the advantage of providing an alternative way of forming a mixed interface between the copper-containing interconnect material of the interconnect element and the first dielectric material of the first dielectric layer that is deposited on the interconnect element. The mixed interface fabricated according to the method of the invention provides a particularly strong adhesion. As a consequence, the interconnect element is better protected against electromigration, which in turn results in a particularly long lifetime of the interconnect element and of the semiconductor device.

Implanting particles into the first dielectric layer and the interconnect element is a process that can be very accurately controlled and performed quickly. There is a large choice of particles that can be used for implantation in order to achieve a desired performance. Also, a desired concentration profile of the particles can be achieved with high precision by techniques, which are known per se. For instance, a desired profile can be achieved by selecting a suitable acceleration voltage and particle concentration, by a sequence of steps at different acceleration voltages, or by one or more implantation steps using different particles.

In comparison with an implantation technique into a Cu interconnect element with an exposed Cu surface, the use of an implantation of particles into the interconnect element through the first dielectric layer has the further advantage that the copper-containing interconnect material cannot be re-sputtered in the implantation process. Re-sputtering would in fact occur in an implantation process into an exposed surface of the interconnect element. Such re-sputtering of Cu would create a high risk of increasing the copper concentration in an insulating neighborhood, if provided, of the connect element, which typically is formed by a dielectric layer. A contamination of neighboring insulating layers with Cu could create undesired current paths. This would form a high reliability risk. Since the implantation step of the method of the invention is performed through the first dielectric layer, such re-sputtering cannot occur. Therefore, the method of the invention ensures a high reliability of the semiconductor device also under this angle of consideration.

A further advantage of the method of the invention is that the processing time needed for fabricating the mixed interface according to the method of the invention is particularly short.

In summary, the method of the invention improves the formation of a diffusion-barrier cap on the interconnect element and achieves a high reliability and short processing times.

In the following, embodiments of the method of the first aspect of the invention will be described. The embodiments can be combined with each other, unless stated otherwise or unless respective features of different embodiments exclude each other.

In one embodiment, a substrate is provided, in which the interconnect element is arranged in a lateral neighborhood of a second dielectric layer. Typically, the interconnect element is embedded laterally in the dielectric layer, separated from the dielectric layer only by a diffusion barrier. In this embodiment, the first dielectric layer is not only deposited on the interconnect element, but also on the second dielectric layer.

In other words, a mixed interface is also formed between the first and second dielectric layers by the processing of the present embodiment in the implantation step. This has the advantage of enhancing the adhesion of the second dielectric layer on the first dielectric layer and thus solving existing adhesion problems.

The interface between the first and second dielectric layers is known to be a weak interface with low adhesion in semiconductor devices, especially in devices, where the second dielectric material is a low-k material. Such devices play an important role because they apply to some current and expected future fabrication technologies. A low adhesion between the first and second dielectric layers forms an issue in packaging. Previous solutions to solve this problem involved a plasma treatment of the low-k dielectric material prior to the deposition of the second dielectric layer, which typically forms a dielectric barrier. However, such plasma treatment tends to degrade the low-k dielectric material in top regions exposed to the plasma, which in turn also degrades deeper regions of the low-k material and thus increases the effective k-value. In the present embodiment, however, an implantation through the second dielectric layer can be controlled very precisely to avoid degrading the first dielectric material. In one embodiment, the implantation of particles is performed so as to provide a maximum intensity of implanted particles at the interface between the first and second dielectric materials. Therefore, the precise control of the intermixing between the first and second dielectric materials at the interface of the first and second dielectric layers improves the adhesion between the two layers and thus the mechanical properties of the semiconductor device with respect to packaging, without degrading the first dielectric material. This is particularly important for the case where the first dielectric material has a low or ultra-low k-value.

This embodiment has the further advantage of providing an improved reliability with respect to the reliability criterion of time-dependent dielectric breakdown (TDDB). The TDDB criterion is a measure for a time span that is necessary to create a short cut between two interconnect elements, which are kept at two different voltage levels. A typical TDDB criterion is that an extrapolated time span at 0.1 MV/cm should be higher than 10 years, wherein the device is kept at a temperature of 100° C.

With the presence of an intermixed interface between the first and second dielectric layers, an interface is created without traps. Without an intermixed interface between the dielectric layers, defects and moisture would be concentrated in an interface region. That would create traps and therefore give rise to a conduction path between neighboring interconnect elements. This is avoided by providing the intermixed interface between the first and second dielectric layers.

In a further embodiment, the first dielectric material is SiCN. In other embodiments, the dielectric material is SiOCN, SiC, or SiN. Also, combinations of the mentioned materials are possible. The mentioned materials for the first dielectric layer have good diffusion barrier properties against the diffusion of copper from the interconnect element into neighboring layer.

Suitable particles for implantation can be provided as atoms, ions, molecules or clusters. The term particle is thus used herein as a generic term that comprises atoms, ions, molecules or clusters as different embodiments. Examples of particles comprise for instance a metal component, a metal oxide, argon (Ar), carbon (C), nitrogen (N), or silicon (Si).

When using a metal component for implantation, it should be provided with a very low concentration in the first dielectric layer and, if present, in the second dielectric layer, unless it is an oxide-based metal component.

Note that the second dielectric layer is in one embodiment not a barrier against copper diffusion before the implantation process. In this embodiment, an implantation of Si and N through the first dielectric layer onto the Cu-containing interconnect material leads to the formation of a CuSiN layer, which will act as a barrier against Cu diffusion. In this embodiment, therefore, a diffusion-barrier cap on the interconnect element is formed during the implantation process through the first dielectric layer. This embodiment has the advantage of providing a reduced dielectric layer thickness and of allowing the use of a low-k barrier. This in turn enhances the signal propagation performance of the semiconductor device of the present embodiment.

According to a second aspect of the present invention a semiconductor device is provided. The semiconductor device comprises:

an interconnect element of a copper-containing interconnect material; and

a first dielectric layer of a first dielectric material that covers the interconnect element.

In the semiconductor device of the second aspect of the invention, implanted particles are present in the first dielectric layer and in the interconnect element, and wherein a first interface region between the first dielectric layer and the interconnect element forms a diffusion-barrier against a diffusion of copper and comprises a mixture of the interconnect material and the first dielectric material.

The semiconductor device of the second aspect of the invention shares the advantages of the method of the first aspect of the invention, which is suitable for fabricating it. In particular, the semiconductor device of the second aspect has an improved first interface region between the Cu-containing interconnect material and the first dielectric layer. This first interface region provides a diffusion-barrier and comprises a mixture of the interconnect material and the first dielectric material. Furthermore, implanted particles are present in the first dielectric layer and the interconnect element. The presence of implanted particles is detectable for instance by secondary ion mass spectroscopy (SIMS). Implanted particles have a typical concentration profile across the layers, into which they are implanted. This implantation profile is very well known and depends, among other parameters, on the acceleration voltage of the implanted particles and specific material properties of the particles and the layers, into which the materials are implanted. Therefore, implanted particles can easily be distinguished from particles which are incorporated into the layers of the semiconductor device by other techniques, such as diffusion or in-situ incorporation during layer growth.

The semiconductor device of the second aspect of the invention has an improved adhesion between the Cu-containing interconnect material and the dielectric material by providing the mixed first interface region between the interconnect element and the first dielectric layer. This increases the lifetime of the semiconductor device in particular because it reduces electromigration problems during operation of the device.

In the following, embodiments of the semiconductor device of the second aspect of the invention will be described. The embodiments can be combined with each other, unless otherwise stated or unless respective features of different embodiments exclude each other.

In one embodiment, the semiconductor device has a second dielectric layer of a second dielectric material that is arranged in a lateral neighborhood of the interconnect element. In this embodiment, the first dielectric layer also covers the second dielectric layer, and the implanted particles are also present in the first and second dielectric layers. A second interface region is provided between the first and second dielectric layers. The second interface region comprises a mixture of the first dielectric material and the second dielectric material.

The advantages of this embodiment have been described in detail in the context of the corresponding embodiment of the method of the first aspect of the invention. In summary, this semiconductor device has an improved adhesion also between the first and second dielectric layers by providing a mixed interface in the form of the second interface region. This improves the TDDB lifetime by avoiding conduction paths between neighboring interconnect elements.

In a further embodiment, a concentration profile of the implanted particles in a direction from the first dielectric layer to the second dielectric layer has a maximum that is located in the second interface region. This way, any damage to the second dielectric layer in deeper layer sections, i.e., sections that have a larger distance from the first dielectric layer, is kept as low as possible.

Preferred embodiments of the invention are also defined in the dependent claims.

### BRIEF DESCRIPTION OF THE DRAWINGS

The invention will now be explained in more detail with reference to the drawings in which

FIGS. 1 to 3 show an embodiment of a method for fabricating a semiconductor device; and

FIG. 4 shows a section of an interconnect stack of a semiconductor device according to an embodiment of the invention.

### DETAILED DESCRIPTION OF EMBODIMENTS

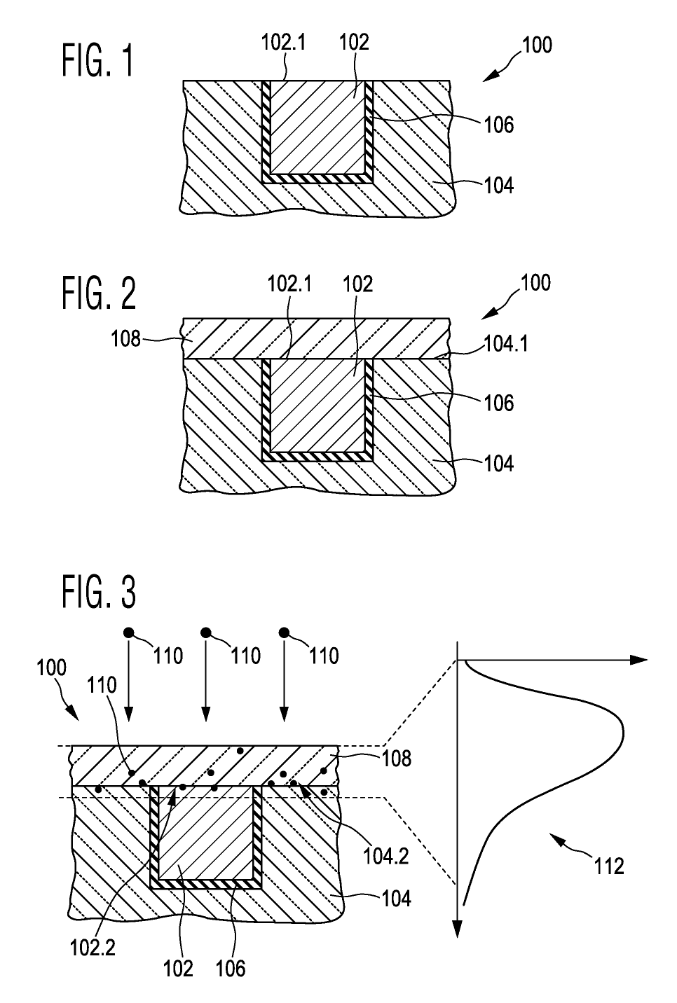

FIGS. 1 to 3 show an embodiment of a method for fabricating a semiconductor device 100 in schematic and simplified cross-sectional views.

FIGS. 1 to 3 schematically show only a section of the semiconductor device 100, which is relevant for illustrating this embodiment of the method of the present invention. The section shown contains an interconnect element 102, which is embedded in an ultra-low-k dielectric layer 104, which in the language of the claims forms the second dielectric layer. The interconnect element is substantially made of Cu. The interconnect element 102 is separated from the ultra-low-k dielectric layer 104 by a diffusion barrier layer 106, which extends along the sidewalls and the bottom of the interconnect element 102.

Note that other embodiment do not use an ultra-low-k dielectric layer 104. However, the present invention is particularly useful for application in the context of the fabrication of semiconductor devices in processing technologies with most advanced scaling, such as the 65 nm or even smaller technology nodes. An ultra-low-k dielectric layer 104 is used to reduce the capacity of the interconnect stack.

The semiconductor device 100 is shown at an intermediate processing stage in FIG. 1. At this processing stage, an interconnect level of an interconnect stack has been formed in a known processing technology such as a damascene or dual damascene technology, which both are known in the art per se. Note, however, that in the context of the invention any processing technology to reach the processing stage of FIG. 1 can be used. At the processing stage shown, the semiconductor device 100 forms a substrate for the subsequent processing, which will be described in the following. The substrate has a surface 102.1 of the interconnect element 102, which is exposed, i. e. not covered by any layer at this processing stage.

Subsequently, the interconnect element 102 and the dielectric layer 104 are covered by another dielectric layer 108. The result of this step is shown in FIG. 2. In the language of the claims, the dielectric layer 108 forms the first dielectric layer, and, as mentioned before, the ultra-low-k dielectric layer 104 forms the second dielectric layer.

In one embodiment, the dielectric layer 108 forms a dielectric diffusion barrier against Cu-diffusion. It is in exemplary embodiments made of SiCN, SiOCN, SiC, SiN, or another dielectric material that is known to form a dielectric barrier suitable for deposition on a Cu interconnect element. The dielectric barrier that is formed by the dielectric layer 108 thus serves to prevent the diffusion of Cu from the interconnect element 102 into layers, which are to be deposited in subsequent processing steps, such as an additional interconnect level. The dielectric layer 108 and the diffusion barrier 106 therefore have the combined effect of preventing Cu diffusion from the interconnect element 102 into any neighboring layers.

However, the interface, which was formed on the previous surface 102.1 of the interconnect element 102 and which for simplicity is referred to with the same reference numeral, has rather poor adhesion properties. This has been described in a previous part of the present application The same holds for an interface 104.1 between the ultra-low-k dielectric layer 104 and the dielectric layer 108.

The adhesion properties of the interfaces 102.1 and 104.1 are improved during a subsequent implantation step, the result of which is shown in FIG. 3. The implantation step is performed so as to achieve a mixing of adjacent layers in interface regions 102.2 and 104.2., i.e., at the former interfaces 102.1 and 104.1 between the dielectric layer 108 on one side and the interconnect element 102 and the ultra-low-k dielectric layer 104, respectively, on the other side.

The implantation step uses particles. The particles may also be provided in the form of clusters in one embodiment. The particles can be made of Si, N, C, Ar, or a metal component. Since metal components other than metal oxides bear the risk of forming undesired current paths in the ultra-low-k dielectric layer 104, the concentration of such metal components, which are not metal oxides, should be kept very low.

It should be noted that in the present embodiment the implantation step does not serve to form a dielectric barrier layer. The dielectric barrier is already present in the form of the dielectric layer 108. Instead, it serves to form the mixed interface regions 102.2 and 104.2, which have improved adhesion properties. Improved adhesion between the dielectric layer 108 and the Cu interconnect element 102 helps to increase the lifetime of the interconnect element, and therefore, of the semiconductor device 100, by reducing undesired electromigration effects. The mixed interface 104.2 between the dielectric layer 108 and the underlying ultra-low-k dielectric layer 104 helps to avoid undesired conduction paths between neighboring interconnect elements (TDDB improvement, as described earlier).

Depending on the processing conditions during implantation, the surface of the dielectric layer 108 can also be modified in order to enhance the diffusion-barrier properties.

Note that the dielectric material of the dielectric layer 108 need not necessarily form a diffusion barrier against Cu diffusion. In one embodiment, Si and N are implanted through the dielectric layer 108 after its deposition to form a CuSiN layer that substantially forms the mixed interface region 102.2. Only this CuSiN layer forms a barrier against Cu diffusion in this embodiment. This way, a diffusion-barrier cap with very low thickness can be provided, in comparison with other techniques used for the self-aligned formation of diffusion-barrier caps on interconnect elements. Furthermore, this diffusion-barrier cap formed by the proposed processing has a low dielectric constant k. This enhances the signal propagation performance of the interconnect stack.

Regarding the processing conditions of the implantation step, the particles are chosen according to the desired effect, such as just described. Furthermore, acceleration voltages used during the implantation step are chosen to form a desired concentration profile of the implanted particles within the semiconductor device 100. Specifically, the acceleration voltage is in one embodiment chosen to provide a rather sharp maximum of the particle concentration within the semiconductor device in the interface regions 102.2 and 104.2. A diagram with a typical concentration profile 112 is schematically shown in the right side of FIG. 3. The diagram is rotated by 90 degrees in comparison with conventional representation. That is, a concentration of the particles is shown as a function of position in the direction indicated by the abscissa, which points from the first dielectric layer to the interconnect element and perpendicular to the surface. This direction can suitably also be referred to as the depth direction. The position range covered is indicated by dashed lines in FIG. 3. Note that the profile shown is only of illustrative nature and not meant to allow a determination of a position of a concentration maximum or a with of the profile.

One embodiment uses different concentration profiles for the different interface regions 102.2 and 104.2, for instance to achieve different extensions of the mixed interface regions in the depth direction. The different concentration profiles can be achieved in a single implantation step. This can be achieved by exploiting the different scattering processes of one type of particles occurring in different materials, namely, Cu and ultra-low-dielectric materials. In another embodiment, different implantation steps are used for the different regions. Here, an implantation mask can be used to cover the regions that shall not be implanted in a respective implantation step.

Concentration profiles of particles generated by implantation typically have a rather sharp increase to a concentration maximum, followed by a concentration decrease with increasing depth from the surface. The decrease after the maximum is often described as a “tail” because low concentrations of the implanted particles can be detected over a larger depth range. The implantation process is very well understood and can be controlled to achieve highly sophisticated concentration patterns. In one embodiment, several implantation steps are used to define a specific concentration profile. The different implantation steps may for instance involve the implantation of different particles with different acceleration voltages, or the implantation of particles of the same type with different acceleration voltages. Other known techniques for fabricating a desired concentration profile by implantation can of course be used as an alternative or in combination with the mentioned techniques.

The implantation of particles through the dielectric layer 108 has the advantage of avoiding Cu re-sputtering effects that occur when implanting the particles into an exposed Cu surface, for instance at the processing stage shown in FIG. 1. Cu re-sputtering leads to undesired concentration of Cu in the neighboring ultra-low-k dielectric layer 104, which could create undesired current paths to neighboring interconnect elements.

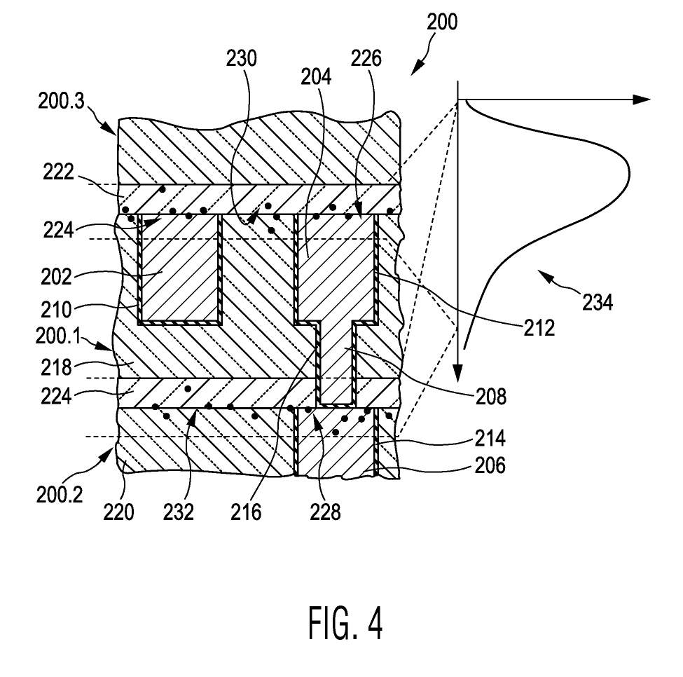

FIG. 4 shows a section of an interconnect stack of a semiconductor device 200 according to an embodiment of the invention. The semiconductor device has interconnect elements 202, 204, and 206 and a via 208 between the interconnect elements 204 and 206. The interconnect elements 202 to 206 and the via are made of Cu. The interconnect elements 202 to 206 and the via 208 are laterally confined by diffusion-barrier liners 210, 212, 214, and 216, respectively. The interconnect elements are laterally embedded in ultra-low-k dielectric layers 218 and 220. The interconnect elements 202 and 204 are arranged on a first interconnect level 200.1 and the interconnect element 206 is arranged on an underlying interconnect level 200.2. Furthermore, an interconnect level 200.3 is shown on top of the interconnect level 200.1, but does not contain interconnect elements in the shown section of the semiconductor device 200. Dielectric layers 222 and 224 are arranged so as to cover top faces of the interconnect elements 202, 204, and 206, respectively. Mixed interfaces 224, 226, and 228 between the Cu interconnect elements 202, 204, and 206 and the respective dielectric layers 222, and 224 form diffusion barriers against Cu diffusion. In one embodiment, the dielectric layers 222 and 224 do not form diffusion barriers. In this embodiment, the mixed interface regions 224, 226, and 228 form diffusion-barrier caps with a particularly low thickness. In another embodiment, also the dielectric layers 222 and 224 form diffusion barriers against Cu diffusion.

Furthermore, second mixed interface regions between the dielectric layers 222 and 224 on one side and the respective underlying ultra-low-k dielectric layers 218 and 220 are provided and indicated by reference labels 230 and 232, respectively. The second mixed interface regions 230 and 232 improve the adhesion of the dielectric layers 222 and 224 on the underlying ultra-low-k dielectric layers 218 and 220, respectively. This helps to improve the TDDB (time dependent dielectric breakdown)-properties of the semiconductor device 200. For it avoids the formation of traps by the presence of defects or moisture at the interfaces between the dielectric layers. Such traps tend to form a conduction path that would create a shortcut between the neighboring interconnect elements 202 and 204, for example, if they are on different voltage levels.

As in FIG. 3, the first and second mixed interface regions are schematically shown with a concentration profile 234 of implanted particles. Details of the concentration profile have been described in the context of the previous embodiment, cf. the description of FIG. 3.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

Any reference signs in the claims should not be construed as limiting the scope.

1. A semiconductor device comprising:
an interconnect element of a copper-containing interconnect material;
a first dielectric layer of a first dielectric material that covers the interconnect element;
wherein implanted particles are present in the first dielectric layer and in the interconnect element, and wherein a first interface region between the first dielectric layer and the interconnect element forms a diffusion-barrier against a diffusion of copper and comprises a mixture of the interconnect material and of the first dielectric material.

2. The semiconductor device of claim 1, wherein
a second dielectric layer of a second dielectric material that is arranged in a lateral neighborhood of the interconnect element;
the first dielectric layer also covers the second dielectric layer,
the implanted particles are also present in the first and second dielectric layers, and wherein
a second interface region between the first and second dielectric layers comprises a mixture of the first dielectric material and the second dielectric material.

3. The semiconductor device of claim 1, wherein a concentration profile of the implanted particles in a direction from the first dielectric layer to the interconnect element has a maximum that is located in the first interface region.

4. The semiconductor device of claim 2, wherein a concentration profile of the implanted particles in a direction from the first dielectric layer to the second dielectric layer has a maximum that is located in the second interface region.

5. The semiconductor device of claim 1, wherein the implanted particles are either atoms, ions, molecules or clusters.

6. The semiconductor device of claim 1, wherein the implanted particles comprise Si, N, C, Ar, a metal component, or a metal oxide.

7. The semiconductor element of claim 1, wherein the first dielectric material comprises SiCN, SiOCN, SiC, or SiN.

8. A method for fabricating a semiconductor device, comprising the steps:
providing a substrate with an interconnect element of a copper-containing interconnect material that has an exposed surface;
depositing a first dielectric layer of a first dielectric material on the exposed surface of the interconnect element;
implanting particles into the first dielectric layer and the interconnect element so as to let the interconnect material mix with the first dielectric material in a first interface region between the interconnect element and the first dielectric layer.

19. The method of claim 8, wherein:
the step of providing a substrate comprises providing a substrate, in which the interconnect element is arranged in a lateral neighborhood of a second dielectric layer of a second dielectric material,
the first dielectric layer is also deposited on the second dielectric layer, and particles are also implanted into the first and second dielectric layers, so as to mix the first and second dielectric materials in a second interface region between the first and second dielectric layers.

10. The method of claim 8, wherein the first dielectric material does not form a barrier against diffusion of copper, and wherein Si and N are implanted so as to form a CuSiN layer in the first interface region.
